(19) United States
(12) Patent Application Publication
(10) Pub. No.: US 2026/0172034 A1
(43) Pub. Date: Jun. 18, 2026

(54) PROGRAMMABLE ELEMENT ARRAY

(71) Applicant: 4DS Memory Limited, West Perth WA (AU)

(72) Inventor: Joseph Tzou, Mountain View, CA (US)

(73) Assignee: 4DS Memory Limited, West Perth WA (AU)

(21) Appl. No.: 18/978,772

(22) Filed: Dec. 12, 2024

(51) Int. Cl. H03K 19/173

(52) U.S. Cl. CPC H03K 19/1733

(57) ABSTRACT

An electronic circuit is disclosed. The circuit includes addressable memory elements, each having a changeable state; programming circuits, each programming circuit configured to control the changeable state of one of the addressable memory elements, where the controlled changeable states are each controlled according to programming code data, where a first subset of the programming circuits is connected to a first word line, where a second subset of the programming circuits is connected to a first bit line, and where one of the programming circuits is included in both the first and second subsets of programming circuits; and one or more program programmable function blocks, each programmable function block having selectable functionalities, where the program programmable function blocks each include one or more of the addressable memory elements, and where the selectable functionalities are selectable by the changing the changeable states of the included addressable memory elements.

### BACKGROUND

Technical Field

The present disclosure generally relates to controlling a set of programmable function blocks, as well as to programming the programmable function blocks.

### Background

Some systems use a number of programmable function blocks in order to perform, for example, a number of selectable signal or data processing functions. Effective systems, circuits, and methods for programming the programmable function blocks is desirable. The systems are particularly advantageous for high computational load applications, such as artificial intelligence training and execution, graphical processing, and central processing units, among others.

### SUMMARY

One embodiment is an electronic circuit, including a plurality of addressable memory elements, each having a changeable state; a plurality of programming circuits, each programming circuit configured to control the changeable state of one of the addressable memory elements, where the controlled changeable states are each controlled according to programming code data, where a first subset of the programming circuits is connected to a first word line, where a second subset of the programming circuits is connected to a first bit line, and where one of the programming circuits is included in both the first and second subsets of programming circuits; and one or more program programmable function blocks, each programmable function block having a plurality of selectable functionalities, where the program programmable function blocks each include one or more of the addressable memory elements, and where the selectable functionalities are selectable by the changing the changeable states of the included addressable memory elements.

Another embodiment is an electronic system, including an array of programmable circuits, each including a plurality of addressable memory elements, each having a changeable state, a plurality of programming circuits, each programming circuit configured to control the changeable state of one of the addressable memory elements, where the controlled changeable states are each controlled according to programming code data, where a first subset of the programming circuits is connected to a first word line, where a second subset of the programming circuits is connected to a first bit line, and where one of the programming circuits is included in both the first and second subsets of programming circuits, and one or more program programmable function blocks, each programmable function block having a plurality of selectable functionalities, where the program programmable function blocks each include one or more of the addressable memory elements, and where the selectable functionalities are selectable by the changing the changeable states of the included addressable memory elements; and a processor, configured to transmit programming code data to the array to program the programmable function blocks, to transmit input data to the programmable function blocks, and to receive output data from the programmable function blocks, where the output data corresponds with the input data as processed by the programmable function blocks according to functionalities corresponding with the programming code data.

Another embodiment is a method of generating processed data with a plurality of programmable function blocks, the method including receiving a plurality of programming signals at an array; changing states of memory elements of the programmable function blocks in response to receiving the programming signals, where the changed states of the memory elements correspond with the received programming signals; receiving input signals; and without performing an address read operation to access data of the memory elements after the states of the memory elements are changed, processing the input signals according to the received programming signals to generate processed data, where the processed data corresponds with the received input signals and corresponds.

### BRIEF DESCRIPTION OF DRAWINGS

For a more complete understanding of one or more embodiments of the present disclosure, and the advantages thereof, reference is now made to the following descriptions taken in conjunction with the accompanying drawings.

FIG. 1 illustrates a schematic circuit block diagram of a programmable function block according to some embodiments.

FIG. 2 illustrates a schematic circuit block diagram of a programmable function block according to some embodiments.

FIG. 3 illustrates a schematic circuit block diagram of an array of programmable function blocks according to some embodiments.

FIG. 4 illustrates a schematic circuit block diagram of a programmable function block according to some embodiments.

FIG. 5 illustrates a schematic circuit block diagram of a programmable function block according to some embodiments.

FIG. 6 illustrates a schematic circuit block diagram of a programmable function block having a control circuit and a multifunction element according to some embodiments.

FIG. 7 illustrates a control circuit according to some embodiments.

FIG. 8 illustrates a multifunction element according to some embodiments.

FIG. 9 illustrates a multifunction element according to some embodiments.

FIG. 10 illustrates a multifunction element according to some embodiments.

FIG. 11 illustrates a schematic circuit block diagram of a programmable function block according to some embodiments.

FIG. 12 illustrates a schematic circuit block diagram of an array of programmable function blocks according to some embodiments.

FIG. 13 illustrates a schematic flowchart diagram of a method of generating data with a number of programmable function blocks according to some embodiments.

FIG. 14 illustrates a schematic flowchart diagram of a method of processing data with a number of programmable function blocks according to some embodiments.

Corresponding numerals and symbols in the different figures generally refer to corresponding parts unless otherwise indicated. The figures are drawn to illustrate the relevant aspects of the embodiments and are not necessarily drawn to scale. The edges of features drawn in the figures do not necessarily indicate the termination of the extent of the feature.

### DETAILED DESCRIPTION

Illustrative embodiments of the system and method of the present disclosure are described below. In the interest of clarity, all features of an actual implementation may not be described in this specification. It will of course be appreciated that in the development of any such actual embodiment, numerous implementation-specific decisions may be made to achieve the developer's specific goals, such as compliance with system-related and business-related constraints, which will vary from one implementation to another. Moreover, it should be appreciated that such a development effort might be complex and time-consuming but would nevertheless be a routine undertaking for those of ordinary skill in the art having the benefit of this disclosure.

Reference may be made herein to the spatial relationships between various components and to the spatial orientation of various aspects of components as the devices are depicted in the attached drawings. However, as will be recognized by those skilled in the art after a complete reading of the present disclosure, the devices, members, apparatuses, etc. described herein may be positioned in any desired orientation. Thus, the use of terms such as “above,” “below,” “upper,” “lower,” or other like terms to describe a spatial relationship between various components or to describe the spatial orientation of aspects of such components should be understood to describe a relative relationship between the components or a spatial orientation of aspects of such components, respectively, as the device described herein may be oriented in any desired direction.

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

Some current methods for programming programmable circuits is slower than desired. For example, code for programming the circuits may be stored in a non-volatile array, such as Flash memory. In addition, to change the code, the programmable circuits are shut off, and the code is written into the non-volatile array. Subsequently, to change the functionality of the programmable circuits, the code is read from the non-volatile array with a memory read operation, and the code is stored in registers local to the programmable circuits.

The time delay between changing code to reprograming the programmable circuits is very long. For example, for some applications, such as Artificial Intelligent (AI) and other computationally intensive applications, a processing circuit with an array of programmable circuits having a fast programming time is beneficial.

In certain embodiments discussed herein, memory elements, such as non-volatile memory elements, are integrated with programmable circuits, where the data states of the memory elements determine the functionality of the programmable circuits. Accordingly, storing the code data in the memory elements programs the programmable circuits, and no subsequent memory read operation is necessary.

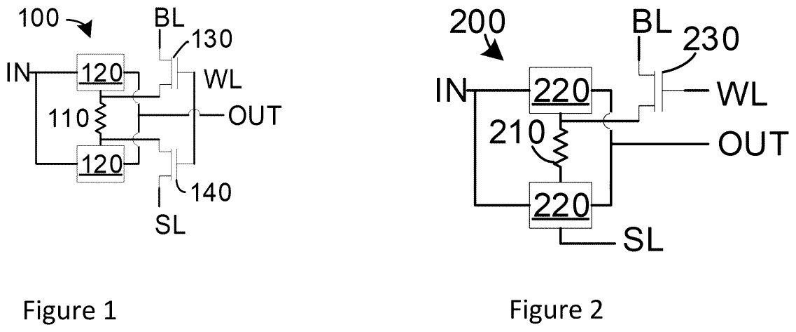

FIG. 1 illustrates a schematic circuit block diagram of a programmable function block 100 according to some embodiments.

In the illustrated embodiment, programmable function block 100 includes memory element 110, processing circuitry 120, and programming switches 130 and 140. In some embodiments, memory element 110 is addressable, and memory element 110 and programming switches 130 and 140 form at least part of an addressable programming circuit, which is used to program programmable function block 110.

In some embodiments, memory element 110 is non-volatile. For example, in some embodiments, memory element 110 includes at least one of: a flash memory cell, a resistive memory (ReRAM) cell, a megnetoresistive RAM (MRAM) cell, and other types of non-volatile memory cells.

The state of memory element 110 is programmed using programming switches 130 and 140. In the illustrated embodiment, memory element 110 is programmed using address signals, such as a bit line signal at bit line BL, a word line signal at word line WL, and a select line signal at select line SL. For example, in some embodiments, applying a first programming signal (voltage) across memory element 110 causes memory element 110 to have a first conductive state, and applying a second programming signal (voltage) across memory element 110 causes memory element 110 to have a second conductive state.

Accordingly, to program programmable function block 100, a circuit, such as a processor or another circuit in a system, may apply either the first programming voltage or the second programming voltage across bit line BL and select line SL, and may apply a word line signal to the word line WL causing programming switches 130 and 140 to be conductive.

In the illustrated embodiment, processing circuitry 120 receives an input signal at node IN. The input signal may be received, for example, from another circuit. For example, a processor or another circuit in a system may transmit the input signal to processing circuitry 120. In response to the input signal, processing circuitry 120 generates an output signal at node OUT, where the output signal corresponds with the input signal and corresponds with a particular selectable function of processing circuitry 120. In the illustrated embodiment, processing circuitry 120 is configured to perform either of two selectable input data processing functions to generate the output signal, and which of the two selectable functions processing circuitry 120 performs is determined by the conductivity state of memory element 110.

In some embodiments, memory element 110 includes a volatile memory cell.

In some embodiments, a different programming circuit is used to program memory element 110. For example, a different programming circuit may be configured to provide signals to memory element 110, and may include circuitry suitable for providing the signals so as to cause memory element 110 to adopt desired states according to the technology and type of memory element 110 being used.

FIG. 2 illustrates a schematic circuit block diagram of a programmable function block 200 according to some embodiments.

In the illustrated embodiment, programmable function block 200 includes memory element 210, processing circuitry 220, and programming switch 230. Memory element 210, programming switch 230, and a portion of processing circuitry 220 form at least part of a programming circuit, which is used to program programmable function block 200.

In some embodiments, memory element 210 is non-volatile.

The state of memory element 210 is programmed using programming switch 230 and a portion of processing circuitry 220. In the illustrated embodiment, memory element 210 is programmed using address signals, such as a bit line signal at bit line BL, and a word line signal at word line WL, a select line signal at select line SL, and additionally with an input signal at node IN. For example, in some embodiments, applying a suitable input to input node IN and applying a first programming voltage across memory element 210 causes memory element 210 to have a first conductive state, and applying a suitable input to input node IN and a second programming voltage across memory element 210 causes memory element 210 to have a second conductive state.

Accordingly, to program programmable function block 200, a circuit, such as a processor or another circuit in a system, may apply a suitable input to input node IN, either the first programming voltage or the second programming voltage across bit line BL and select line SL, and a word line signal to the word line WL causing programming switch 230 to be conductive.

In the illustrated embodiment, processing circuitry 220 receives an input signal at node IN. The input signal may be received, for example, from another circuit. For example a processor or another circuit in a system may transmit the input signal to processing circuitry 220. In response to the input signal, processing circuitry 220 generates an output signal at node OUT, where the output signal corresponds with the input signal and corresponds with a particular selectable function of processing circuitry 220. In the illustrated embodiment, processing circuitry 220 is configured to perform either of two selectable input data processing functions to generate the output signal, and which of the two selectable functions processing circuitry 220 performs is determined by the conductivity state of memory element 210.

In some embodiments, memory element 210 includes a volatile memory cell.

In some embodiments, a different programming circuit is used to program memory element 210. For example, a different programming circuit may be configured to provide signals to memory element 210, and may include circuitry suitable for providing the signals so as to cause memory element 210 to adopt desired states according to the technology and type of memory element 210 being used.

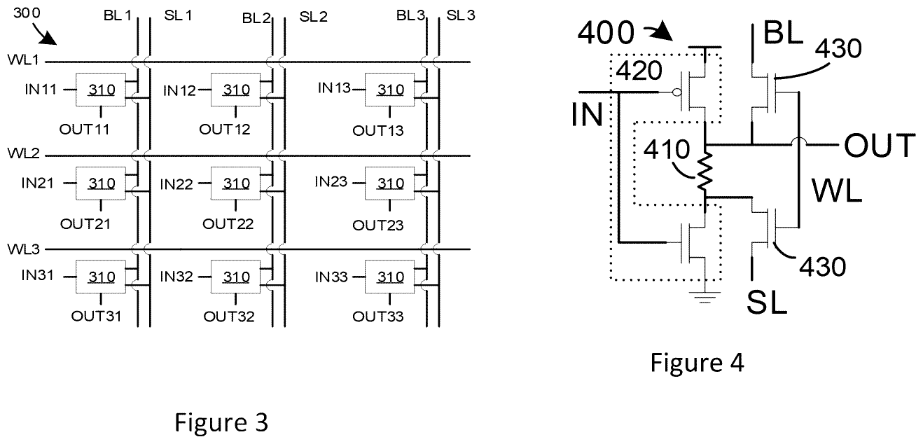

FIG. 3 illustrates a schematic circuit block diagram of a two-dimensional array 300 of programmable function blocks 310 according to some embodiments. In some embodiments, programmable function blocks 310 can include features similar or identical to one or both of programmable function blocks 100 and 200.

Each of the programmable function blocks 310 may be programmed using address signals applied to one of bit lines BL1, BL2, and BL3, one of word lines WL1, WL2, and WL3, one of select lines SL1, SL2, and SL3, and in some embodiments, an input signal applied to the input INxx of the corresponding programmable function block 310. The programmable function block 310 may be programmed using aspects of the techniques described above with reference to programmable function blocks 100 and 200.

In some embodiments, multiple programmable function blocks 310 are programmed simultaneously or substantially simultaneously. For example, the word lines WL1, WL2, and WL3 corresponding with rows of programmable function blocks 310 may be sequentially applied an active signal while the others of word lines WL1, WL2, and WL3 are applied an inactive signal. In addition, while the active signal is applied to one of the word lines WL1, WL2, and WL3, programming code data applied across the bit lines BL1, BL2, and BL3 and the select lines SL1, SL2, and SL3. In response, the programmable function blocks 310 of the row of programmable function blocks 310 corresponding with the word line receiving the active signal are programmed with code data corresponding with their respective pairs of bit lines BL1, BL2, and BL3 and select lines SL1, SL2, and SL3.

In some embodiments, other programming methods are used.

Once the programmable function blocks 310 are programmed, the functionality of the programmable function blocks 310 correspond with the programming code data. No additional read operation is needed. Accordingly, storing the code data in the memory elements of programmable function blocks 310 programs the programmable function blocks 310. Therefore, once the programmable function blocks 310 are programmed, each of the programmable function blocks 310 generates an output signal at its output node OUTxx, where the generated output signal corresponds with the input signal at its input node INxx, and corresponds with the particular selectable function of its processing circuitry, as selected by the code data with which it was programmed.

In some embodiments, multiple programmable function blocks 310 are programmed so as to have identical input/output functionality. In some embodiments, multiple programmable function blocks 310 in a contiguous portion of programmable function blocks of array 300 are programmed so as to have identical input/output functionality. In some embodiments, adjacent programmable function blocks 310 are programmed so as to have identical input/output functionality. In some embodiments, multiple programmable function blocks 310 are programmed so as to have different input/output functionality. In some embodiments, multiple programmable function blocks 310 in a contiguous portion of programmable function blocks of array 300 are programmed so as to have different input/output functionality. In some embodiments, adjacent programmable function blocks 310 are programmed so as to have different input/output functionality. In some embodiments, array 300 includes one or more function blocks which are not programmable.

In some embodiments, FIG. 3 generally represents spatial relationships of physical embodiments of one or more elements of array 300. For example, in some embodiments, the programmable function blocks 310 are physically formed in an array. In some embodiments, one or more portions of each of the programmable function blocks 310 is physically formed in an array.

FIG. 4 illustrates a schematic circuit block diagram of a programmable function block 400 according to some embodiments.

In the illustrated embodiment, programmable function block 400 includes memory element 410, processing circuitry 420, and programming switches 430. Memory element 410, and programming switches 430 form at least part of a programming circuit, which is used to program programmable function block 400.

In the illustrated embodiment, programmable function block 400 is an inverter which can be enabled or disabled according to the state of memory element 410.

In this embodiment, the state of memory element 410 is programmed using techniques described with reference to programmable function block 100. Additional or alternative programming techniques and/or features may be used.

In the illustrated embodiment, once programmable function block 400 is programmed, processing circuitry 420 receives an input signal at node IN, and generates an output signal at node OUT, where the output signal is selectably an inverted version of the input signal if the programmable function block 400 is enabled by the programmed state.

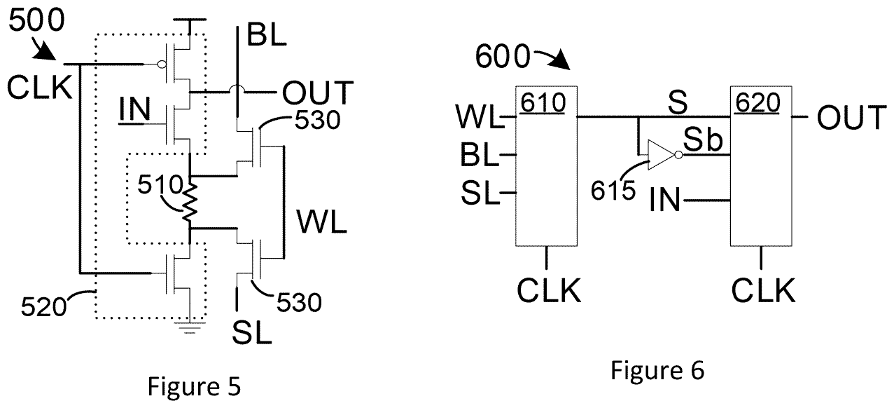

FIG. 5 illustrates a schematic circuit block diagram of a programmable function block 500 according to some embodiments.

In the illustrated embodiment, programmable function block 500 includes memory element 510, processing circuitry 520, and programming switches 530. Memory element 510, and programming switches 530 form at least part of a programming circuit, which is used to program programmable function block 500.

In the illustrated embodiment, programmable function block 500 is a dynamic clocked inverter which can be enabled or disabled according to the state of memory element 510.

In this embodiment, the state of memory element 510 is programmed using techniques described with reference to programmable function block 100. Additional or alternative programming techniques and/or features may be used.

In the illustrated embodiment, once programmable function block 500 is programmed, processing circuitry 520 receives an input signal at node IN, and, during the active (high) portion of clock signal CLK, generates an output signal at node OUT, where the output signal is selectably an inverted version of the input signal if the programmable function block 500 is enabled by the programmed state or a HIGH signal if the programmable function block 500 is disabled by the programmed state.

FIG. 6 illustrates a schematic circuit block diagram of a programmable function block 600 having a dynamic control circuit 610, an inverter 615, and a dynamic multifunction element 620 according to some embodiments. In alternative embodiments, one or both of control circuit 610 and multifunction element 620 are not dynamic circuits.

Control circuit 610 includes a memory element which may be programmed using word line WL, bit line BL, and select line SL, for example, using techniques similar or identical to those discussed elsewhere herein. Control circuit 610 generates an output at node S corresponding with the state of the memory element, as programmed. In addition, inverter 615 generates an output at node Sb based on the state of the output at node S.

Multifunction element 620 receives signals S and Sb, and uses signals at nodes S and Sb to select one of a number of selectable functions. In addition, multifunction element 620 receives an input signal at node IN and generates an output signal at node OUT based on the input signal and based on the functionality selected according to the signals at nodes S and Sb.

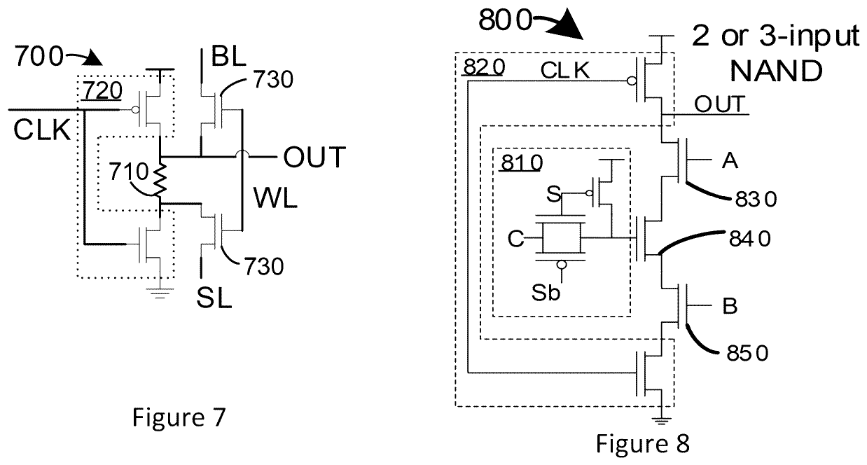

FIG. 7 illustrates a schematic circuit block diagram of a control circuit 700 according to some embodiments.

In the illustrated embodiment, control circuit 700 includes memory element 710, dynamic inverter circuit 720, and programming switches 730. Memory element 710, and programming switches 730 form at least part of a programming circuit, which is used to program control circuit 700.

In the illustrated embodiment, control circuit 700 generates an output at node OUT corresponding with the state of the memory element 710, as programmed.

In this embodiment, the state of memory element 710 is programmed using techniques described with reference to programmable function block 100. Additional or alternative programming techniques and/or features may be used.

In the illustrated embodiment, once control circuit 700 is programmed, during the active (high) portion of clock signal CLK, control circuit 700 generates an output signal at node OUT, where the output signal is selectably a LOW signal if the programmable function block 700 is enabled by the programmed state or a HIGH signal if the programmable function block 700 is disabled by the programmed state.

FIG. 8 illustrates a multifunction element 800 according to some embodiments. In the illustrated embodiment, multifunction element 800 is either a two-input NAND gate or a three-input NAND gate. In the illustrated embodiment, multifunction element 800 includes function selector circuit 810, dynamic inverter circuit 820, NAND switches 830 and 850, and selectable NAND switch 840.

Function selector circuit 810 receives complementary select signals S and Sb, and selectively connects selectable NAND switch 840 to either logic input C or to a HIGH signal. As a result, selectable NAND switch 840 either functions as a NAND switch (if connected to logic input C) or functions as a short, substantially removing it from the logic operation of multifunction element 800..

Accordingly, when receiving select signals indicating that multifunction element 800 is to function as a two-input NAND gate, selectable NAND switch 840 receives a HIGH gate input, and NAND switches 830 and 850 receive logic inputs A and B. As a result, during the active (high) portion of clock signal CLK, multifunction element 800 generates an output signal at node OUT, where the output signal is a logical NAND of the logic inputs A and B, regardless of the logic state at logic input C.

Alternatively, when receiving select signals indicating that multifunction element 800 is to function as a three-input NAND gate, selectable NAND switch 840 receives a logic input C, and NAND switches 830 and 850 receive logic inputs A and B. Therefore, during the active (high) portion of clock signal CLK, multifunction element 800 generates an output signal at node OUT, where the output signal is a logical NAND of the logic inputs A, B, and C.

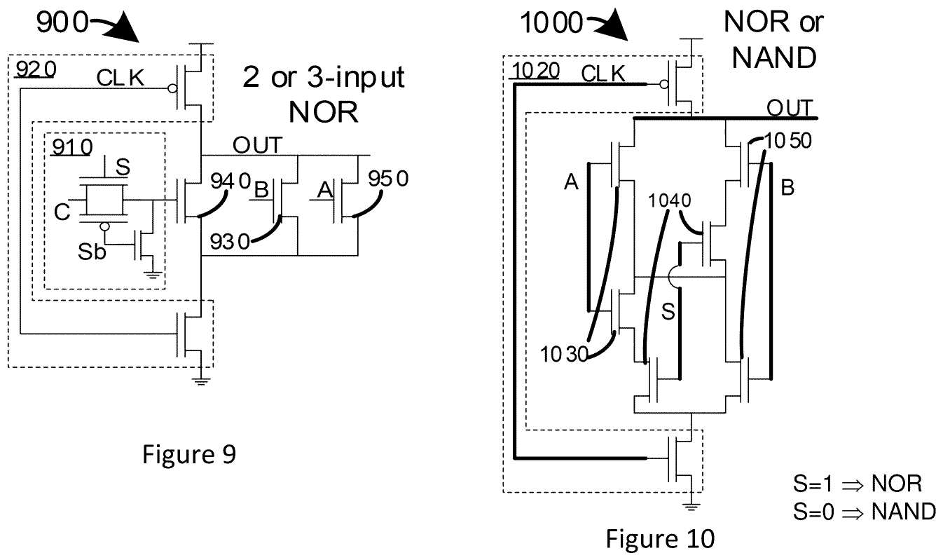

FIG. 9 illustrates a multifunction element 900 according to some embodiments. In the illustrated embodiment, multifunction element 900 is either a two-input NOR gate or a three-input NOR gate. In the illustrated embodiment, multifunction element 900 includes function selector circuit 910, dynamic inverter circuit 920, NOR switches 930 and 950, and selectable NOR switch 940.

Function selector circuit 910 receives complementary select signals S and Sb, and selectively connects selectable NOR switch 940 to either logic input C or to a LOW signal. As a result, selectable NOR switch 940 either functions as a NOR switch (if connected to logic input C) or functions as an open, substantially removing it from the logic operation of multifunction element 900.

Accordingly, when receiving select signals indicating that multifunction element 900 is to function as a two-input NOR gate, selectable NOR switch 940 receives a LOW gate signal input, and NOR switches 930 and 950 receive logic inputs A and B. As a result, during the active (high) portion of clock signal CLK, multifunction element 900 generates an output signal at node OUT, where the output signal is a logical NOR of the logic inputs A and B, regardless of the logic state at logic input C.

Alternatively, when receiving select signals indicating that multifunction element 900 is to function as a three-input NOR gate, selectable NOR switch 940 receives a logic input C, and NOR switches 930 and 950 receive logic inputs A and B. Therefore, during the active (high) portion of clock signal CLK, multifunction element 900 generates an output signal at node OUT, where the output signal is a logical NOR of the logic inputs A, B, and C.

FIG. 10 illustrates a multifunction element 1000 according to some embodiments. In the illustrated embodiment, multifunction element 1000 is either a two-input NOR gate or a two-input NAND gate. In the illustrated embodiment, multifunction element 1000 includes dynamic inverter circuit 1020, logic switches 1030 and 1050, and function selection switches 1040.

Function selection switches 1040 receives select signal S, and, as a result, function either as opens or as shorts. As the circuit indicates, the functionality of multifunction element 1000 depends on the conductivity state of function selection switches 1040, where multifunction element 1000 functions as a dynamic two-input NOR gate in response to selectable switches 1040 operating as shorts, and where multifunction element 1000 functions as a dynamic two-input NAND gate in response to function selection switches 1040 operating as opens.

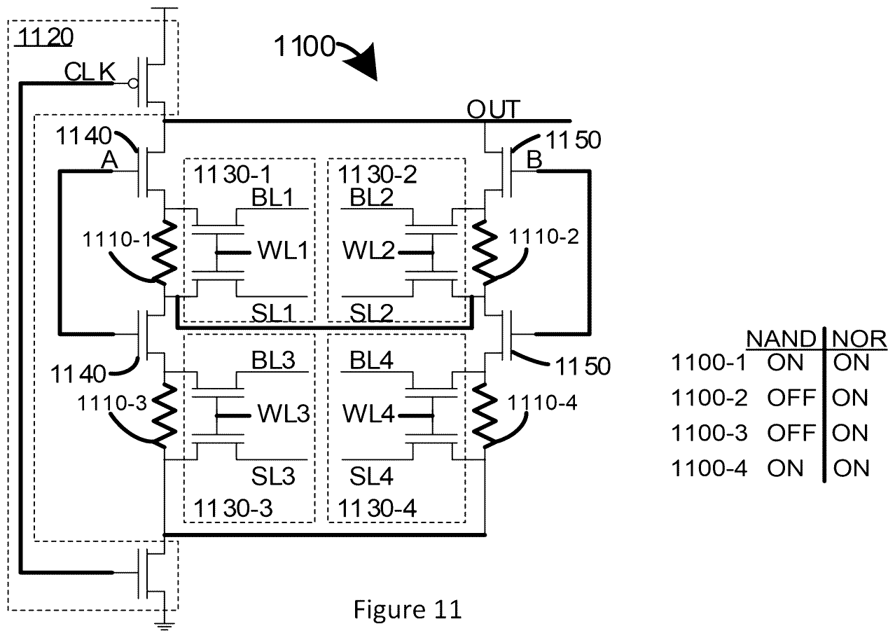

FIG. 11 illustrates a schematic circuit block diagram of a programmable function block 1100 according to some embodiments.

In the illustrated embodiment, programmable function block 1100 operates as either a two-input NOR gate or a two-input NAND gate. In the illustrated embodiment, programmable function block 1100 includes dynamic inverter circuit 1120, memory elements 1110-1, 1110-2, 1110-3, and 1110-4, logic switches 1140 and 1150, and programming switch networks 1130-1, 1130-2, 1130-3, and 1130-4.

Memory elements 1110-1, 1110-2, 1110-3, and 1110-4, and programming switch networks 1130-1, 1130-2, 1130-3, and 1130-4 form at least part of a programming circuit, which is used to program programmable function block 1100. Memory elements 1110-1, 1110-2, 1110-3, and 1110-4 may be programmed using techniques described, for example, with reference to programmable function block 100. Additional or alternative programming techniques and/or features may be used to program memory elements 1110-1, 1110-2, 1110-3, and 1110-4.

In the illustrated embodiment, when the conductive states of memory elements 1110-1, 1110-2, 1110-3, and 1110-4 are programmed to be conductive, programmable function block 1100 functions as a dynamic clocked two-input NOR gate. As a consequence, during the active (high) portion of clock signal CLK, programmable function block 1100 generates an output signal at node OUT, where the output signal is a logical NOR of the input signals received at nodes A and B.

Alternatively, when the conductive states of memory elements 1110-1 and 1110-4 are programmed to be conductive and the conductive states of memory elements 1110-1 and 1110-4 are programmed to be non-conductive, programmable function block 1100 functions as a dynamic clocked two-input NAND gate. As a consequence, during the active (high) portion of clock signal CLK, programmable function block 1100 generates an output signal at node OUT, where the output signal is a logical NAND of the input signals received at nodes A and B.

In alternative embodiments, memory elements 1110-1 and 1110-4 are omitted and are replaced with electrical shorts. In addition, programming switch networks 1130-1 and 1130-4 may be omitted. These alternative embodiments have advantageously fewer elements, and, therefore, requires less area and may require less power to operate. Embodiments including memory elements 1110-1 and 1110-4 and programming switch networks 1130-1 and 1130-4, for example, as illustrated, may advantageously have more symmetric, consistent, or otherwise ideal switching characteristics.

In some embodiments, one or more of the memory elements and corresponding programming switch networks is omitted, and is replaced with a pass transistor or a pass gate configured to receive a select signal or a complementary select signal generated, for example, by a control circuit having features similar or identical to control circuits discussed elsewhere herein. In some embodiments, all of the memory elements and corresponding programming switch networks are omitted, and are each replaced with a pass transistor or a pass gate configured to receive a select signal or a complementary select signal generated, for example, by a control circuit having features similar or identical to control circuits discussed elsewhere herein. Embodiments having one or more pass transistors or pass gates instead of memory elements and corresponding programming switch networks may be considered a multifunction element or at least partly a multifunction element having features similar or identical to those multifunction elements discussed elsewhere herein.

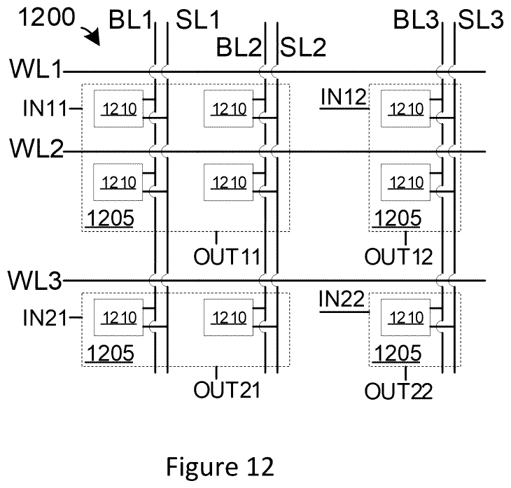

FIG. 12 illustrates a schematic circuit block diagram of a two-dimensional array 1200 of programming circuits 1210 according to some embodiments. In some embodiments, programming circuits 1210 can include features similar or identical to programming circuits discussed elsewhere herein. For example, each programming circuit 1210 may include an addressable memory element and one or more programming switch networks.

With reference to FIG. 3, array 300 of programmable function blocks 310 illustrates an embodiment in which each programmable function block 310 includes a single corresponding programming circuit. In contrast, array 1200 illustrates an embodiment in which one or more programmable function blocks 1205 includes multiple programming circuits 1210. Accordingly, to program the programmable function blocks 1205 having multiple programming circuits 1210, each of the multiple programming circuits 1210 of the corresponding programmable function block 1205 is programmed.

In some embodiments, array 1200 includes multiple programmable function blocks 1205, each having multiple programming circuits 1210. In some embodiments, array 1200 includes one or more programmable function blocks 1205 having multiple programming circuits 1210, and includes one or more programmable function blocks 1205 having a single programming circuit 1210. In some embodiments, all of the programmable function blocks 1205 of array 1200 have multiple programming circuits 1210. In some embodiments, array 1200 includes one or more function blocks which are not programmable.

Each of the programming circuits 1210 may be programmed using address signals applied to one of bit lines BL1, BL2, and BL3, one of word lines WL1, WL2, and WL3, and one of select lines SL1, SL2, and SL3, and in some embodiments, an input signal applied to one or more inputs of the corresponding programmable function block. The programming circuits 1210 may be programmed using aspects of the techniques described above with reference to one or both of programmable function blocks 100 and 200.

In some embodiments, multiple programming circuits 1210 are programmed simultaneously or substantially simultaneously. For example, the word lines WL1, WL2, and WL3 corresponding with rows of programming circuits 1210 may be sequentially applied an active signal while the others of word lines WL1, WL2, and WL3 are applied an inactive signal. In addition, while the active signal is applied to one of the word lines WL1, WL2, and WL3 programming code data applied across the bit lines BL1, BL2, and BL3 and the select lines SL1, SL2, and SL3. In response, the programming circuits 1210 of the row of programming circuits 1210 corresponding with the word line receiving the active signal are programmed with code data corresponding with their respective pairs of bit lines BL1, BL2, and BL3 and select lines SL1, SL2, and SL3.

In some embodiments, other programming methods are used.

Once the programming circuits 1210 are used to program the programmable function blocks 1205, the functionality of each of the programmable function blocks 1205 corresponds with the programming code data used for programming the corresponding programmable function blocks 1205. Accordingly, storing the code data in the memory elements of programming circuits 1210 programs the corresponding programmable function blocks 1205. Therefore, once the programming circuits 1210 are programmed, in response to an input signal at its input node INxx, each of the programmable function blocks 1205 generates an output signal at its output node OUTxx, where the generated output signal corresponds with the input signal at its input node INxx, and corresponds with the particular selectable function of its processing circuitry, as selected by the code data with which it was programmed.

In some embodiments, multiple programmable function blocks 1205 are programmed so as to have identical input/output functionality. In some embodiments, multiple programmable function blocks 1205 in a contiguous portion of programmable function block from array 1200 are programmed so as to have identical input/output functionality. In some embodiments, adjacent programmable function blocks 1205 are programmed so as to have identical input/output functionality. In some embodiments, multiple programmable function blocks 1205 are programmed so as to have different input/output functionality. In some embodiments, multiple programmable function blocks 1205 in a contiguous portion of array 1200 are programmed so as to have different input/output functionality. In some embodiments, adjacent programmable function blocks 1205 are programmed so as to have different input/output functionality.

In some embodiments, FIG. 12 generally represents spatial relationships of physical embodiments of one or more elements of array 1200. For example, in some embodiments, the programmable function blocks 1205 are physically formed in an array. In some embodiments, each of one or more portions of the programmable function blocks 1205 is physically formed in an array. In some embodiments, the programming circuits 1210 are physically formed in an array. In some embodiments, the programming circuits 1210 are physically formed in an array, and other circuitry of the programmable function blocks 1205 is physically located within and among the programming circuits 1210 of the array.

For convenience and clarity, the examples discussed herein have fewer elements than many anticipated embodiments. For example, some embodiments have hundreds, thousands, or millions of programmable function blocks, where each programmable function block may have many programming circuits.

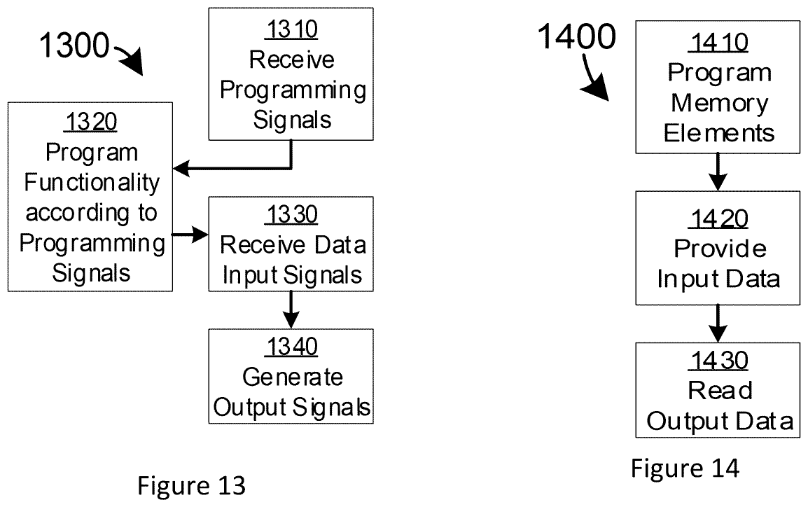

FIG. 13 illustrates a schematic flowchart diagram of a method 1300 of generating data with one or more programmable function blocks according to some embodiments. The method may be performed by a programmable function block having features similar or identical to features of one or more of the programmable function blocks discussed herein. In some embodiments, the method may be performed substantially simultaneously by a number of programmable function blocks, for example, in or distributed through an array, for example, having features similar or identical as those of the arrays discussed herein. For example, the method may be performed substantially simultaneously by an array of programmable function blocks, or may be performed by a number of programmable function blocks having memory elements formed in an array. In some embodiments, a single programmable function block performs the method.

At 1310, programming signals are received. For example, one or more word lines corresponding with rows of an array of programming circuits of programmable function blocks may be sequentially applied an active signal while the others of the word lines are applied an inactive signal. In addition, while the active signal is applied to the one word line, programming code data may be applied across bit lines and select lines of the array.

At 1320, in response to receiving the programming signals, the programmable function blocks of the row of programmable function blocks corresponding with the word line receiving the active signal are programmed with code data corresponding with their respective pairs of bit lines and select lines. The programming code data causes the programmed programmable function blocks to be configured to function according to functionality corresponding with the programming code data with which they are programmed.

It is worth noting that at least in some embodiments, the programmable function blocks are programmed in response to their memory elements receiving the programming signals. Accordingly, to program the programmable function blocks, it is not necessary to determine data stored in the memory elements with a separate address read operation identifying a subset of memory elements of a memory element array.

At 1330, data input signals are received. For example, the programmable function blocks may receive input signals from another circuit. For example, a processor or another circuit in a system may transmit the input signals to the programmable function blocks.

At 1340, output signals are generated. In response to the input signals received at 1330, the programmable function blocks, having been programmed at 1320, process the input signals according to the programming code data received by the programmable function blocks at 1310 to generate output signals, where the output signals respectively correspond with the received input signals and respectively correspond with a particular selectable function of the code data received by the programmable function blocks at 1310.

FIG. 14 illustrates a schematic flowchart diagram of a method 1400 of processing data with a number of programmable function blocks according to some embodiments. The method may be performed by a circuit, such as a processor or another circuit, communicating with a programmable function block having features similar or identical to features of one or more of the programmable function blocks discussed herein. In some embodiments, the circuit may communicate with a number of programmable function blocks, for example, in or distributed through an array, for example, having features similar or identical as those of the arrays discussed herein. For example, the circuit may communicate with an array of programmable function blocks, or a number of programmable function blocks having memory elements formed in an array. In some embodiments, the circuit communicates with a single programmable function block.

At 1410, programming signals are transmitted. For example, the circuit may apply an active signal to one or more word lines corresponding with rows of programming circuits of programmable function blocks of an array while applying an inactive signal to others of the word lines. In addition, while the active signal is applied to the one word line, the circuit may apply programming code data across bit lines and select lines of the array. In response to receiving the programming signals, the programmable function blocks of the row of programmable function blocks corresponding with the word line receiving the active signal are programmed with code data corresponding with their respective pairs of bit lines and select lines. The programming code data causes the programmed programmable function blocks to be configured to function according to functionality corresponding with the programming code data with which they are programmed.

It is worth noting that at least in some embodiments, the programmable function blocks are programmed in response to their memory elements receiving the programming code data. Accordingly, to program the programmable function blocks, it is not necessary to determine data stored in the memory elements with a separate address read operation identifying a subset of memory elements of a memory element array.

At 1420, data input signals are transmitted. For example, the circuit may apply input signals to the programmable function blocks of the array.

At 1430, output signals are received. In response to the input signals received at 1420, the programmable function blocks, having been programmed at 1410, process the input signals according to the programming code data received by the programmable function blocks at 1410 to generate output signals, where the output signals respectively correspond with the received input signals and respectively correspond with a particular selectable function of the code data received by the programmable function blocks at 1410.

In some embodiments, the circuit performing method 1400 includes or has access to a memory storing executable instructions, which, when executed, cause the circuit to perform method 1400. In some embodiments, the input signals are retrieved from the memory and transmitted to the programmable function blocks of the array. In some embodiments, the output signals generated by the programmable function blocks are transmitted to and stored by the memory.

While the principles of the disclosure have been described above in connection with specific apparatuses and methods, it is to be understood that this description is made only by way of example and not as limitation on the scope of the disclosure.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. In addition, the logic flows depicted in the accompanying figures and/or described herein do not necessarily require the particular order shown, or sequential order, to achieve desirable results. Other implementations may be within the scope of the following claims.

What is claimed is:

1. An electronic circuit, comprising:
a plurality of addressable memory elements, each having a changeable state;
a plurality of programming circuits, each programming circuit configured to control the changeable state of one of the addressable memory elements, wherein the controlled changeable states are each controlled according to programming code data, wherein a first subset of the programming circuits is connected to a first word line, wherein a second subset of the programming circuits is connected to a first bit line, and wherein one of the programming circuits is included in both the first and second subsets of programming circuits; and
one or more program programmable function blocks, each programmable function block having a plurality of selectable functionalities, wherein the program programmable function blocks each comprise one or more of the addressable memory elements, and wherein the selectable functionalities are selectable by the changing the changeable states of the comprised addressable memory elements.

2. The electronic circuit of claim 1, wherein the addressable memory elements are arranged in an array.

3. The electronic circuit of claim 1, wherein the programming circuits are arranged in an array.

4. The electronic circuit of claim 1, wherein one or more of the program programmable function blocks each comprise two or more of the addressable memory elements.

5. The electronic circuit of claim 1, wherein at least one of the program programmable function blocks comprises:
a programmable control circuit comprising at least one of the addressable memory elements, and configured to generate a select signal based on the changeable state of the at least one addressable memory element; and
a multifunction element having the plurality of selectable functionalities, wherein the selectable functionalities is selectable by the select signal.

6. The electronic circuit of claim 5, wherein the at least one program programmable function block further comprises one or more programming switches configured to control the changeable state of the at least one addressable memory element.

7. The electronic circuit of claim 5, wherein the multifunction element comprises a function selection switch configured to select one of the functionalities of the multifunction element according to the select signal.

8. The electronic circuit of claim 5, wherein the multifunction element comprises a plurality of function selection switch configured to collectively select one of the functionalities of the multifunction element according to the select signal.

9. An electronic system, comprising:
an array of programmable circuits, each comprising:
a plurality of addressable memory elements, each having a changeable state,
a plurality of programming circuits, each programming circuit configured to control the changeable state of one of the addressable memory elements, wherein the controlled changeable states are each controlled according to programming code data, wherein a first subset of the programming circuits is connected to a first word line, wherein a second subset of the programming circuits is connected to a first bit line, and wherein one of the programming circuits is included in both the first and second subsets of programming circuits, and
one or more program programmable function blocks, each programmable function block having a plurality of selectable functionalities, wherein the program programmable function blocks each comprise one or more of the addressable memory elements, and wherein the selectable functionalities are selectable by the changing the changeable states of the comprised addressable memory elements; and
a processor, configured to transmit programming code data to the array to program the programmable function blocks, to transmit input data to the programmable function blocks, and to receive output data from the programmable function blocks, wherein the output data corresponds with the input data as processed by the programmable function blocks according to functionalities corresponding with the programming code data.

10. The electronic system of claim 9, wherein the addressable memory elements are arranged in an array.

11. The electronic system of claim 9, wherein the programming circuits are arranged in an array.

12. The electronic system of claim 9, wherein one or more of the program programmable function blocks each comprise two or more of the addressable memory elements.

13. The electronic system of claim 9, wherein at least one of the program programmable function blocks comprises:
a programmable control circuit comprising at least one of the addressable memory elements, and configured to generate a select signal based on the changeable state of the at least one addressable memory element; and
a multifunction element having the plurality of selectable functionalities, wherein the selectable functionalities is selectable by the select signal.

14. The electronic system of claim 13, wherein the at least one program programmable function block further comprises one or more programming switches configured to control the changeable state of the at least one addressable memory element.

15. The electronic system of claim 13, wherein the multifunction element comprises a function selection switch configured to select one of the functionalities of the multifunction element according to the select signal.

16. The electronic system of claim 13, wherein the multifunction element comprises a plurality of function selection switch configured to collectively select one of the functionalities of the multifunction element according to the select signal.

17. A method of generating processed data with a plurality of programmable function blocks, the method comprising:
receiving a plurality of programming signals at an array;
changing states of memory elements of the programmable function blocks in response to receiving the programming signals, wherein the changed states of the memory elements correspond with the received programming signals;
receiving input signals; and
without performing an address read operation to access data of the memory elements after the states of the memory elements are changed, processing the input signals according to the received programming signals to generate processed data, wherein the processed data corresponds with the received input signals and corresponds.

18. The method of claim 17, wherein changing the states of the memory elements causes the programmable functions blocks to change functionality.

19. The method of claim 17, wherein the programming signals are received from a processor, the method further comprising, transmitting the processed data to the processor.

20. The method of claim 17, wherein the memory elements are non-volatile.
